(19) United States
(12) Patent Application Publication
(10) Pub. No.: US 2015/0144952 A1
(43) Pub. Date: May 28, 2015

(54) DISPLAY SUBSTRATE, METHOD OF MANUFACTURING THE SAME, AND DISPLAY DEVICE INCLUDING THE SAME

(71) Applicant: Samsung Display Co., Ltd., Yongin-City (KR)

(72) Inventors: Sun-Kwang Kim, Suwon-si (KR); Chaun-Gi Choi, Hwaseong-si (KR); Dong-Han Kang, Hwaseong-si (KR); Jae-Sik Kim, Hwaseong-si (KR); Hyeon-Sik Kim, Yongin-si (KR); Woong-Hee Jeong, Seoul (KR)

(21) Appl. No.: 14/521,274

(22) Filed: Oct. 22, 2014

(30) Foreign Application Priority Data
Nov. 27, 2013 (KR) 10-2013-0145254

(51) Int. Cl. H01L 27/32; H01L 29/45; H01L 27/12; H01L 29/786

(52) U.S. Cl. CPC H01L 27/3262; H01L 29/78648; H01L 29/45; H01L 27/124; H01L 27/1259; H01L 2227/323
USPC 257/72; 438/158

(57) ABSTRACT

A display substrate, method of manufacturing the same, and a display device including the same are disclosed. In one aspect, a display substrate includes a first gate electrode formed on a base substrate, a scan line electrically connected to the first gate electrode, a gate insulation layer, an etch stop layer and a passivation layer formed on the base substrate to at least partially overlap the first gate electrode and the scan line, and a data line formed on the passivation layer to at least partially overlap the scan line.

### CROSS-REFERENCE TO RELATED APPLICATIONS

This application claims priority under 35 USC §119 to Korean Patent Applications No. 10-2013-0145254, filed on Nov. 27, 2013 in the Korean Intellectual Property Office (KIPO), the contents of which are incorporated by reference herein in its entirety.

### BACKGROUND

1. Field

The described technology generally relates to a display substrate, a method of manufacturing the same, and a display device including the same.

2. Description of the Related Technology

A display device, such as an organic light-emitting diode (OLED) display or a liquid crystal display (LCD), includes a plurality of pixels on a base substrate and a plurality of signal lines transmitting an electrical signal to each of the pixels. Recently, as the image area of the display device has become larger, the number of the pixels and the complexity of arranging the signal lines have increased.

### SUMMARY OF CERTAIN INVENTIVE ASPECTS

One inventive aspect is a display substrate having improved electrical and operational characteristics.

Another aspect is a method of manufacturing a display substrate having improved electrical and operational characteristics.

Another aspect is a display device including a display substrate having improved electrical and operational characteristics.

Another aspect is a display substrate that includes a first gate electrode formed on the base substrate, a scan line electrically connected to the first gate electrode on the base substrate, a gate insulation layer, an etch stop layer and a passivation layer sequentially formed on the base substrate to cover the first gate electrode and the scan line, and a data line formed on the passivation layer to at least partially overlap with the scan line.

In example embodiments, the scan line can be formed on the same level as that of the first gate electrode, and the scan line can include the same conductive material as that of the first gate electrode.

In example embodiments, the data line can cross over the scan line, and an intersection region of the data line and the scan line can include the gate insulation layer, the etch stop layer and the passivation layer stacked between the scan line and the data line.

In example embodiments, the display substrate can further include an active layer partially covered by the etch stop layer on the gate insulation layer, and a source electrode and a drain electrode formed on the etch stop layer to be electrically connected to the active layer.

In example embodiments, the display substrate can further include a pad electrically connected to the scan line on the base substrate, where the pad can be formed on the same level as that of the scan line, and the pad includes the same conductive material as that of the scan line.

In example embodiments, the pad can include at least one selected from the group consisting of copper (Cu), aluminum (Al), gold (Au), silver (Ag) and tungsten (W).

In example embodiments, the display substrate can further include a barrier conductive layer formed on the pad, where the barrier conductive layer can include the same conductive material as those of the source electrode and the drain electrode.

In example embodiments, the source electrode, the drain electrode and the barrier conductive layer can include at least one selected from the group consisting of titanium (Ti), molybdenum (Mo), titanium nitride, molybdenum nitride and a conductive metal oxide.

In example embodiments, the display substrate can further include a second gate electrode formed on the passivation layer, where each of the first gate electrode and the second gate electrode can overlap with the active layer.

In example embodiments, the second gate electrode can be formed on the same level as that of the data line, and where the second gate electrode can include the same conductive material as that of the data line.

In example embodiments, the display substrate can further include a pixel contact electrically connected to the drain electrode, where the pixel contact can include the same conductive material as that of the data line.

Another aspect is a method of manufacturing a display substrate that can include a step of forming a first gate electrode and a scan line electrically connected to the first gate electrode on the base substrate, a step of forming a gate insulation layer on the base substrate to cover the first gate electrode and the scan line, a step of forming an active layer on the gate insulation layer to overlap with the first gate electrode, a step of forming an etch stop layer on the gate insulation layer to partially cover the active layer, a step of forming a source electrode and a drain electrode on the etch stop layer to be electrically connected to the active layer, a step of forming a passivation layer on the etch stop layer to cover the source electrode and the drain electrode, and a step of forming a data line on the passivation layer to at least partially overlap with the scan line.

In example embodiments, the etch stop layer and the passivation layer can cover the scan line.

In example embodiments, the method of manufacturing the display substrate can further include a step of forming a pad on the base substrate to be electrically connected to the scan line, where the pad can be formed together with the first gate electrode and the scan line by a patterning process using a first conductive layer.

In example embodiments, the method of manufacturing the display substrate can further include a step of partially etching the etch stop layer and the gate insulation layer to form an opening through which the pad is exposed, and a step of forming a barrier conductive layer in contact with the pad via the opening.

In example embodiments, the barrier conductive layer can be formed together with the source electrode and the drain electrode by a patterning process using a second conductive layer, where the second conductive layer can be formed using at least one selected from the group consisting of titanium, molybdenum, titanium nitride, molybdenum nitride and a conductive metal oxide.

In example embodiments, the method of manufacturing the display substrate can further include a step of forming a second gate electrode overlapping with the active layer on the passivation layer.

In example embodiments, the method of manufacturing the display substrate can further include a step of forming a pixel contact electrically connected to the drain electrode on the passivation layer, where the pixel contact can be formed together with the second gate electrode and the data line by a patterning process using a third conductive layer.

Another aspect is a display device that can include a first gate electrode formed on the base substrate, a scan line electrically connected to the first gate electrode on the base substrate, a gate insulation layer, an etch stop layer and a passivation layer sequentially formed on the base substrate to cover the first gate electrode and the scan line, an active layer partially covered by the etch stop layer on the gate insulation layer, a source electrode and a drain electrode formed on the etch stop layer to be electrically connected to the active layer, a data line formed on the passivation layer to at least partially overlap with the scan line, a pixel electrode electrically connected to the drain electrode, a light-emitting layer formed on the pixel electrode, and an opposite electrode formed on the light-emitting layer.

In example embodiments, the display device can further include a second gate electrode formed on the passivation layer to overlap with the active layer, where the second gate electrode can be formed on the same level as that of the data line, and the second gate electrode can include the same conductive material as that of the data line.

Another aspect is a display substrate, comprising: a base substrate; a first gate electrode formed on the base substrate; a scan line electrically connected to the first gate electrode; a gate insulation layer, an etch stop layer and a passivation layer formed on the base substrate to at least partially overlap the first gate electrode and the scan line; and a data line formed on the passivation layer to at least partially overlap the scan line.

In the above display substrate, the scan line is formed on the same level as that of the first gate electrode, and the scan line is formed of the same material as that of the first gate electrode. In the above display substrate, the data line crosses the scan line, and the gate insulation layer, the etch stop layer and the passivation layer are stacked between the scan line and the data line and formed in an intersection region of the data line and the scan line.

The above display substrate further comprises: an active layer at least partially covered by the etch stop layer; and a source electrode and a drain electrode formed on the etch stop layer and electrically connected to the active layer. The above display substrate further comprises a pad electrically connected to the scan line, wherein the pad is formed on the same level as that of the scan line, and wherein the pad is formed of the same material as that of the scan line.

In the above display substrate, the pad is formed using at least one of copper (Cu), aluminum (Al), gold (Au), silver (Ag), tungsten (W) or a combination thereof. The above display substrate further comprises a barrier conductive layer formed on the pad, wherein the barrier conductive layer is formed of the same material as that of the source electrode and the drain electrode. In the above display substrate, the source electrode, the drain electrode and the barrier conductive layer are formed using at least one of titanium (Ti), molybdenum (Mo), titanium nitride, molybdenum nitride, a conductive metal oxide or a combination thereof.

The above display substrate further comprises a second gate electrode formed on the passivation layer, wherein each of the first and second gate electrodes substantially overlaps the active layer. In the above display substrate, the second gate electrode is formed on the same level as that of the data line, wherein the second gate electrode is formed of the same material as that of the data line. The above display substrate further comprises a pixel contact electrically connected to the drain electrode, wherein the pixel contact is formed of the same material as that of the data line.

Another aspect is a method of manufacturing a display substrate, the method comprising: forming a first gate electrode and a scan line to be electrically connected to the first gate electrode on a base substrate; forming a gate insulation layer on the base substrate to substantially cover the first gate electrode and the scan line; forming an active layer on the gate insulation layer to substantially overlap the first gate electrode; forming an etch stop layer on the gate insulation layer to at least partially cover the active layer; forming a source electrode and a drain electrode on the etch stop layer to be electrically connected to the active layer; forming a passivation layer on the etch stop layer to substantially cover the source electrode and the drain electrode; and forming a data line on the passivation layer to at least partially overlap the scan line.

In the above method, the etch stop layer and the passivation layer substantially cover the scan line. The above method further comprises forming a pad on the base substrate to be electrically connected to the scan line, wherein the pad, the first gate electrode and the scan line are formed substantially simultaneously by a patterning process using a first conductive layer. The above method further comprises: partially etching the etch stop layer and the gate insulation layer to form an opening through which the pad is exposed; and forming a barrier conductive layer to be electrically connected to the pad via the opening.

In the above method, the barrier conductive layer, the source electrode and the drain electrode are formed substantially simultaneously by a patterning process using a second conductive layer, wherein the second conductive layer is formed using at least one of titanium, molybdenum, titanium nitride, molybdenum nitride, a conductive metal oxide or a combination thereof. The above method further comprises forming a second gate electrode to at least partially overlap the active layer. The above method further comprises forming a pixel contact electrically connected to the drain electrode, wherein the pixel, the second gate electrode and the data line are formed substantially simultaneously by a patterning process using a third conductive layer.

Another aspect is a display device, comprising: a first gate electrode formed on a base substrate; a scan line electrically connected to the first gate electrode; a gate insulation layer, an etch stop layer and a passivation layer formed on the base substrate to at least partially cover the first gate electrode and the scan line; an active layer at least partially covered by the etch stop layer; a source electrode and a drain electrode formed on the etch stop layer to be electrically connected to the active layer; a data line formed on the passivation layer to at least partially overlap the scan line; a pixel electrode electrically connected to the drain electrode; a light-emitting layer formed on the pixel electrode; and an opposite electrode formed on the light-emitting layer.

The above display device further comprises a second gate electrode formed on the passivation layer to at least partially overlap the active layer, wherein the second gate electrode is formed on the same level as that of the data line, and wherein the second gate electrode is formed of the same material as that of the data line.

Another aspect is a display device, comprising: a pixel circuit; a thin film transistor (TFT) electrically connected to the pixel circuit and including a gate electrode; a scan line configured to provide a scan signal to the gate electrode, wherein the gate electrode and the signal line are formed on the same layer.

The above display device further comprises: a data line configured to provide a data signal to the TFT; and a multi-stacked insulating layer interposed between the scan line and the data line. The above display device further comprises: a pad electrically connected to the scan line; and a barrier conductive layer substantially covering the pad.

According to at least one embodiment, a scan line and a first gate electrode can be electrically connected to each other on the same layer. Thus, an additional contact for connecting the first gate electrode and the scan line to each other is not needed. Further, a multi-stacked insulation layers, e.g., 3-level insulation layers can be interposed between the scan line and the data line so that a parasitic capacitance generated between the scan line and the data line can be reduced. Furthermore, a barrier conductive layer can be formed on a pad, so that an oxidation of the pad can be substantially prevented.

### BRIEF DESCRIPTION OF THE DRAWINGS

FIG. 1 is a cross-sectional view illustrating a display substrate according to example embodiments.

FIG. 2 is a schematic top plan view illustrating a portion of the display substrate of FIG. 1 adjacent to a thin film transistor.

FIG. 3 is a local cross-sectional view illustrating a formation of a channel region in the display substrate of FIG. 1.

FIGS. 4 to 10 are cross-sectional views illustrating a method of manufacturing a display substrate according to example embodiments.

FIG. 11 is a cross-sectional view illustrating a display device according to example embodiments.

### DETAILED DESCRIPTION OF CERTAIN INVENTIVE EMBODIMENTS

Parasitic capacitance can be generated between signal lines that overlap each other. As the number of conductive structures including contacts or bridges increase, contact resistance between the signal lines and the conductive structures can also increase.

Various example embodiments will be described more fully hereinafter with reference to the accompanying drawings, in which some example embodiments are shown. The described technology can, however, be embodied in many different forms and should not be construed as limited to the example embodiments set forth herein. Rather, these example embodiments are provided so that this disclosure will be thorough and complete, and will fully convey the scope of the described technology to those skilled in the art. In the drawings, the sizes and relative sizes of layers and regions can be exaggerated for clarity. Like numerals refer to like elements throughout.

It will be understood that, although the terms first, second, third etc. can be used herein to describe various elements, these elements should not be limited by these terms. These terms are used to distinguish one element from another. Thus, a first element discussed below could be termed a second element without departing from the teachings of the described technology. As used herein, the term “and/or” includes any and all combinations of one or more of the associated listed items.

It will be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the described technology. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the described technology belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

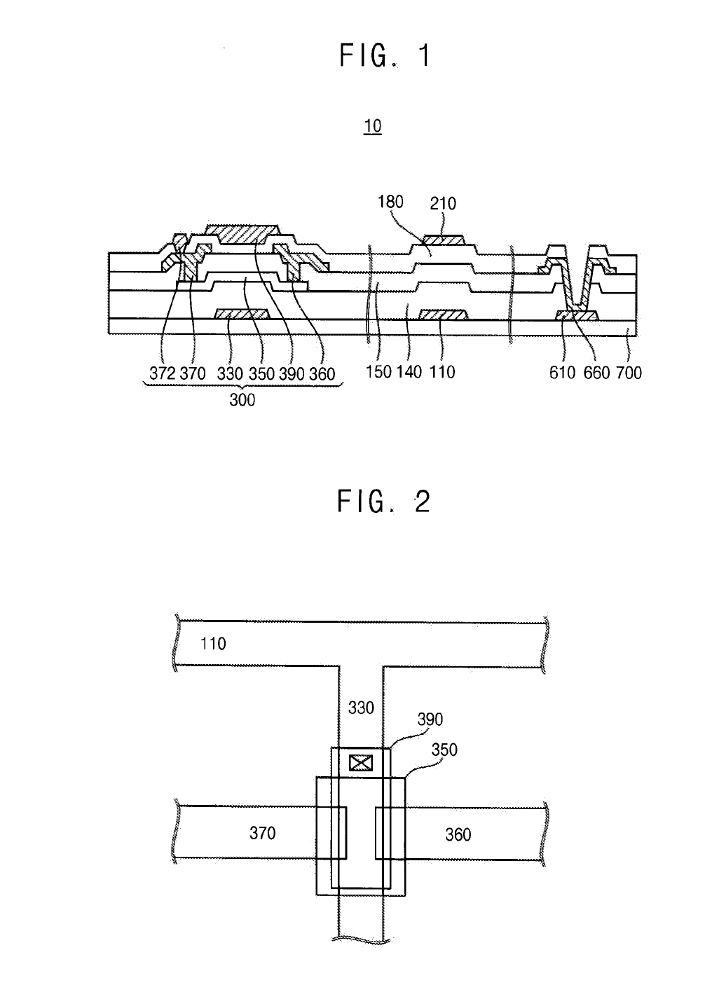

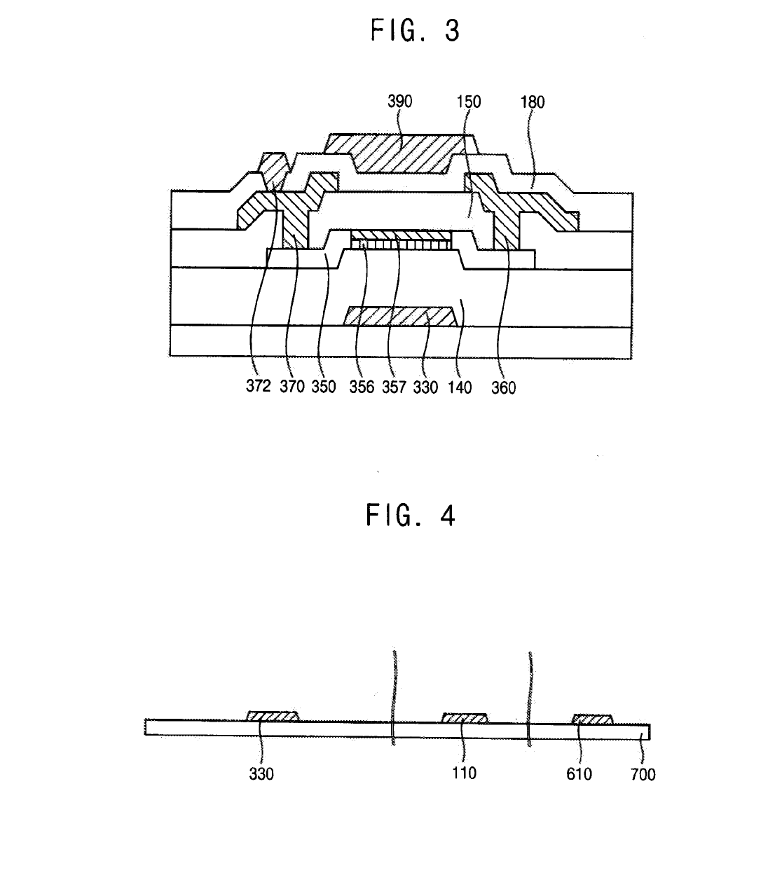

FIG. 1 is a cross-sectional view illustrating a display substrate 10 according to example embodiments. FIG. 2 is a schematic top plan view illustrating a portion of the display substrate 10 of FIG. 1 adjacent to a thin film transistor (TFT). FIG. 3 is a local cross-sectional view illustrating a formation of a channel region in the display substrate 10 of FIG. 1.

In example embodiments, the display substrate 10 can be implemented in a display device such as an OLED display or an LCD.

Referring to FIGS. 1 and 2, the display substrate 10 includes at least one TFT 300 electrically connected to a pixel of the display device, a first signal line 110 and a second signal line 210.

A base substrate 700 is typically made of a glass or plastic formed at least partially of polyethylene terephthalate (PET), polyethylene naphthalate (PEN), polyimide or a combination thereof.

The first signal line 110 can be formed on the base substrate 700. In example embodiments, the first signal line 110 can serve as a scan line providing scan signals to first and second gate electrodes 330 and 390 of the TFT 300. The second signal line 210 can serve as a data line providing data signals to the TFT 300. The first and second signal lines 110 and 210 can extend in different directions from each other. For example, the second signal line 210 can cross the first signal line 110.

In exemplary embodiments, the first and second signal lines 110 and 210 can be formed on different layers or different levels from each other. At least one insulation layer can be interposed at an intersection region of the first and second signal lines 110 and 210. In example embodiments, stacked insulation layers including a gate insulation layer 140, an etch stop layer 150 and a passivation layer 180 can be interposed between the first and second signal lines 110 and 210. The first signal line 110 can be substantially insulated from the second signal line 210 by the stacked insulation layers so that a parasitic capacitance generated between the two signal lines 110 and 210 can be substantially minimized.

Each of the first and second signal lines 110 and 210 can be formed at least partially of a material having a low resistance for rapid signal transfer. Each of the signal lines 110 and 210 can be formed at least partially of a metal, a nitride of the metal or an alloy of the metal. For example, the metal can include copper (Cu), aluminum (Al), gold (Au), silver (Ag), tungsten (W) or a combination thereof. Each of the signal lines 110 and 210 can have a single-layered or multi-layered structure.

Each of the first and second signal lines 110 and 210 can be formed sufficiently thick so as to maintain a sufficiently low resistance. For example, each of the first and second signal lines 110 and 210 can have a thickness of about 2000 angstroms (A), but is not limited thereto.

In example embodiments, the display substrate 10 can further include a pad 610, electrically connected to the first signal line 110. For example, the first signal line 110 can extend a predetermined direction, and the pad 610 can protrude from the first signal line 110.

The pad 610 can receive and transmit a first signal to the first signal line 110. For example, the pad 610 can serve as a scan pad, and the first signal can include a scan signal.

In example embodiments, the pad 610 can be formed on the same layer or the same level as that of the first signal line 110. Further, the pad 610 can be formed at least partially of the same material (e.g., conductive material) as that of the first signal line 110. The pad 610 can have a single-layered or multi-layered structure including the metal, the nitride of the metal or the alloy of the metal.

In example embodiments, a barrier conductive layer 660 can be formed on at least a portion of an upper surface of the pad 610. The barrier conductive layer 660 can substantially prevent the pad 610 from being oxidized by exposure to the atmosphere, e.g., oxygen, water, etc. When the pad 610 is formed of copper, the pad 610 can be easily oxidized after formation of a hole or an opening partially exposing the pad 610. Thus, the barrier conductive layer 660 can substantially cover the exposed portion to substantially prevent the oxidation.

The barrier conductive layer 660 can be formed at least partially of a metal, a nitride of the metal and/or a conductive metal oxide. For example, the barrier conductive layer 660 can be formed at least partially of titanium (Ti), titanium nitride (TiNx), molybdenum (Mo) or molybdenum nitride. The conductive metal oxide can include indium tin oxide (ITO), indium zinc oxide (IZO), aluminum zinc oxide (AZO), tin oxide (SnOx), indium oxide (InOx), gallium oxide (GaOx) or a combination thereof. When the barrier conductive layer 660 is formed of the conductive metal oxide, the barrier conductive layer 660 can have an improved resistance to corrosion and oxidation. Therefore, when the pad 610 is formed of a metal like copper, the pad 610 can be substantially protected from degradation or deterioration caused by the oxidation

The TFT 300 can include a first gate electrode 330 formed on the gate insulation layer 140, an active layer 350, the etch stop layer 150, a source electrode 360, a drain electrode 370, the passivation layer 180 and a second gate electrode 390 substantially sequentially stacked on the base substrate 700.

The first gate electrode 330 can be formed on the base substrate 700, and electrically connected to the first signal line 110 and the pad 610. As illustrated in FIG. 2, the first signal line 110 can extend in a predetermined direction and the first gate electrode 330 can protrude from the first signal line 110.

In exemplary embodiments, as illustrated in FIG. 1, the first gate electrode 330, the first signal line 110 and the pad 610 can be formed on the same layer or the same level. The first gate electrode 330 can be formed at least partially of the same material as those of the first signal line 110 and the pad 610.

The gate insulation layer 140 can substantially cover the first gate electrode 330 and the first signal line 110. In example embodiments, the pad 610 can be at least partially exposed by the gate insulation layer 140. For example, a hole or an opening exposing an upper surface of the pad 610 for an efficient transmittance of the first signal can be formed through the gate insulation layer 140. The barrier conductive layer 660 can be formed on side walls and a bottom portion of the hole or the opening to substantially cover the pad 610.

The gate insulation layer 140 can be formed at least partially of an oxide-based material or an organic insulation material. For example, the gate insulation layer 140 can be formed at least partially of silicon oxide (SiOx), hafnium oxide (HfOx), aluminum oxide (AlOx), zirconium oxide (ZrOx), titanium oxide (TiOx), tantalum oxide (TaOx), a benzocyclobutene (BCB)-based resin, an acryl-based resin or a combination thereof. The gate insulation layer 140 can have a single-layered or multi-layered structure.

The active layer 350 can be formed on the gate insulation layer 140. The active layer 350 can at least partially over the first gate electrode 330. For example, the active layer 350 can be formed on a portion of the gate insulation layer 140 substantially covering the first gate electrode 330. The active layer 350 can be formed at least partially of polysilicon, doped polysilicon, amorphous silicon, doped amorphous silicon, an oxide semiconductor, a doped oxide semiconductor or a combination thereof. The oxide semiconductor can include indium gallium zinc oxide (IGZO), indium tin zinc oxide (ITZO), gallium zinc oxide (GaZnxoy), zinc magnesium oxide (ZnMgxOy), zinc tin oxide (ZnSnxOy), zinc zirconium oxide (ZnZrxOy), zinc oxide, gallium oxide, tin oxide, indium oxide, indium gallium hafnium oxide (IGHO), tin-aluminum-zinc oxide (TAZO), indium-gallium-tin oxide (IGSO) or a combination thereof.

The etch stop layer 150 can be formed on the gate insulation layer 140. The etch stop layer 150 can substantially protect the active layer 350 from damage caused by etching while forming the source and drain electrodes 360 and 370. For example, the etch stop layer 150 can substantially protect a portion of the active layer 350 serving as a channel. The etch stop layer 150 can have a single-layered or multi-layered structure formed at least partially of silicon oxide and/or silicon nitride.

The source and drain electrodes 360 and 370 can be formed on the etch stop layer 150 and can be electrically connected to the active layer 350 via a hole or an opening. For example, the hole or the opening exposing portions of an upper surface of the active layer 350 can be formed in the etch stop layer 150.

The source and drain electrodes 360 and 370 can be formed at least partially of a metal, a nitride of the metal, a conductive metal oxide and/or a transparent conductive material. For example, each electrode 360 and 370 can be formed at least partially of aluminum, an alloy of aluminum, aluminum nitride (AlNx), silver, an alloy of silver, tungsten, tungsten nitride (WNx), nickel (Ni), chrome (Cr), molybdenum, molybdenum nitride, titanium, titanium nitride (TiNx), platinum (Pt), tantalum, neodymium (Nd), scandium (Sc), tantalum nitride (TaNx), strontium ruthenium oxide (SrRuxOy), zinc oxide (ZnOx), ITO, tin oxide, indium oxide, gallium oxide, IZO or a combination thereof. Each of the source electrode 360 and the drain electrode 370 can have a single-layered or multi-layered structure.

In example embodiments, the electrodes 360 and 370 can be formed on the same layer or the same level as that of the barrier conductive layer 660. Each of the source electrode 360 and the drain electrode 370 can be formed at least partially of the same material having the high resistance to corrosion and oxidation as that of the barrier conductive layer 660.

The passivation layer 180 can be formed on the etch stop layer 150 to substantially cover the source and drain electrodes 360 and 370.

The passivation layer 180 can be formed at least partially of an oxide-based material, a nitride-based material, an oxynitride-based material, an organic insulation material, such as silicon oxide, silicon nitride, silicon oxynitride, an acryl-based resin, a polyimide-based resin, a siloxane-based resin or a combination thereof. The passivation layer 180 can have a single-layered or multi-layered structure.

The second gate electrode 390 can be formed on the passivation layer 180. The second gate electrode 380 can at least partially overlap the active layer 350.

In example embodiments, the second gate electrode 390 can be formed on the same layer or the same level as that of the second signal line 210. The second gate electrode 390 can be formed at least partially of the same material as that of the second signal line 210.

In example embodiments, a pixel contact 372 electrically connected to the drain electrode 370 can be formed on the passivation layer 180. The drain electrode 370 can be electrically connected to the pixel electrode via the pixel contact 372. In this embodiment, an electric signal received from the source electrode 360 can be supplied to a pixel via the drain electrode 370 and the pixel contact 372.

The pixel contact 372 can be formed on the same layer or the same level as that of the second gate electrode 390. The pixel contact 372 can be formed at least partially of the same material as that of the second gate electrode 390.

As illustrated in FIG. 3, according to example embodiments, the TFT 300 can include a first gate electrode 330 formed under the active layer 350 and a second gate electrode 390 formed on the active layer 350. Thus, when a predetermined voltage is applied to double gate electrodes 330 and 390, double channel 356 and 357 can be respectively formed at a top portion and a bottom portion of the active layer 350. The electrical signal input received from the source electrode 360 can be supplied to the drain electrode 370. In example embodiments, the first gate electrode 330 can form a first channel 356 at the bottom portion, and the second gate electrode 390 can form a second channel 357 at the top portion. Thus, although the gate insulation layer 140 has a large thickness, double channels 356 and 357 can be sufficiently formed. Further, the TFT 300 can rapidly transmit the electrical signal input from the source electrode 360 to the drain electrode 370. Also, because the gate insulation layer 140 is relatively thick, parasitic capacitance generated between the first and second signal lines 110 and 210 can be reduced.

Generally, a TFT is classified as a bottom gate type transistor when a bottom gate electrode is formed under a bottom portion of the active layer. The TFT is classified as a top gate type transistor when a top gate electrode is formed on a top portion of the active layer. However, when only one gate electrode is formed, a high gate voltage is required to form a channel when the gate insulation layer is formed thick. As a result, the response rate of the TFT can be low. On the other hand, if the gate insulation layer is thin such that the gate voltage is reduced, a parasitic capacitance can be generated between the gate electrode and the data line. The parasitic capacitance can be generated at an intersection region (i.e., crossed region) where the gate line crosses the data line. The parasitic capacitance can reduce the response rate of the TFT because of an added RC-delay.

To solve these problems, the gate line can be separated into the gate line and a scan line. For example, an additional scan line formed at least partially of a metal that has a relatively low resistance can be formed on a lower level or a lower layer of the gate line. A buffer layer can be formed on an upper level or an upper layer of the scan line so that the parasitic capacitance generated in the intersection region can be reduced by the buffer layer. In this example, the scan line can be electrically connected to the gate electrode via an additional contact or bridge. However, if the scan line is separated from the gate line, the manufacture of the display substrate can become complicated. For example, the display substrate implemented in a wide-screen display device needs many additional contacts or bridges which require additional steps and contact regions. Also, because of the additional contacts or bridges, total contact resistance of the scan line can increase, which can lead to additional RC-delays.

Additionally, the scan line can be formed at least partially of copper having relatively low resistance. The pad that is provided with the scan signal can also include the same material as that of the scan line. However, the copper exposed by a hole in the pad can be easily oxidized while hardening the hole. Because the contact resistance of the pad rapidly increases by the oxidation of the pad, the RC-delay can also increase rapidly.

However, according to example embodiments, the first gate electrode 330 and the scan line (i.e., the first signal line 110) can be electrically connected to each other on the same layer or the same level, so that the scan signal can be transmitted to the gate electrodes 330 and 390 without the additional contacts or bridges. Further, because the barrier conductive layer 660 can be formed on the pad 610, the oxidation of pad 610 can be minimized. Furthermore, the parasitic capacitance can be effectively reduced by stacked layers, e.g., 3-level layers including the gate insulation layer 140, the etch stop layer 150 and the passivation layer 180.

FIGS. 4 to 10 are cross-sectional views illustrating a method of manufacturing the display substrate 10 according to example embodiments.

Referring to FIG. 4, the first signal line 110 and the first gate electrode 330 are formed on the base substrate 700. In example embodiments, the pad 610 can further be formed on the base substrate 700. The first gate electrode 330 can be wider than the first signal line 110 and the pad 610. The width of the first signal line 110 can be larger than the width of the pad 610.

For example, the first signal line 110, the first gate electrode 330 and the pad 610 can be formed by a step of forming a first conductive layer and a step of patterning the first conductive layer by a patterning process, e.g., photolithography.

The first conductive layer can be formed at least partially of a metal, e.g., copper, aluminum, gold, silver, tungsten or a combination thereof. Further, the first conductive layer can be formed by sputtering, chemical vapor deposition (CVD), atomic layer deposition (ALD), pulsed laser deposition (PLD), printing or a combination thereof.

The first signal line 110, the first gate electrode 330 and the pad 610 can have a large thickness in order to maintain a sufficiently low resistance. For example, the first signal line 110, the first gate electrode 330 and the pad 610 can have a thickness of about 2000 Å, but is not limited thereto

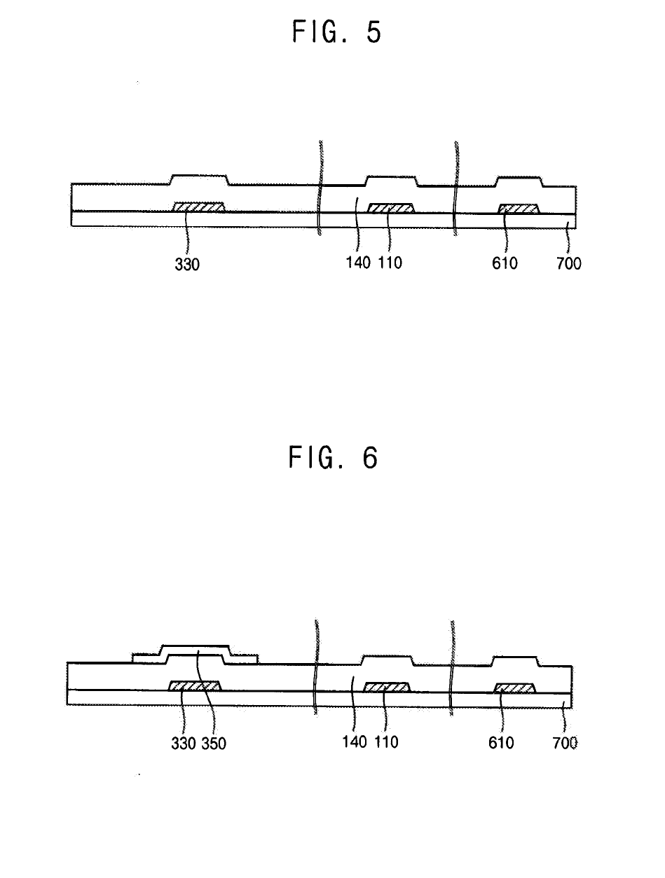

Referring to FIG. 5, the gate insulation layer 140 substantially covering the first signal line 110, the first gate electrode 330 and the pad 610 can be formed on the base substrate 700. The thickness of the gate insulation layer 140 can be greater than the thicknesses of each of the first signal line 110, the first gate 330, and the pad 610. The thickness of the gate insulation layer 140 can be substantially uniform throughout.

The gate insulation layer 140 can be formed by CVD, ALD, spin coating, printing, etc.

Referring to FIG. 6, the active layer 350 can be formed on the gate insulation layer 140. The active layer 350 can at least partially overlap the first gate electrode 330. The width of the active layer 350 can be larger than the width of the first gate electrode 330. The active layer 350 can be formed by a step of forming a semiconductor layer formed at least partially of polysilicon, amorphous silicon or an oxide semiconductor and a step of pattering the semiconductor layer by a patterning process, e.g., photolithography. The oxide semiconductor layer can be formed at least partially of IGZO, ITZO, gallium zinc oxide, IZO, zinc magnesium oxide, zinc tin oxide, zinc zirconium oxide, zinc oxide, gallium oxide, tin oxide, indium oxide, IGHO, TAZO, IGSO or a combination thereof. An impurity can be doped in the semiconductor layer. The active layer 350 can be formed by CVD, sputtering, ALD, printing or a combination thereof.

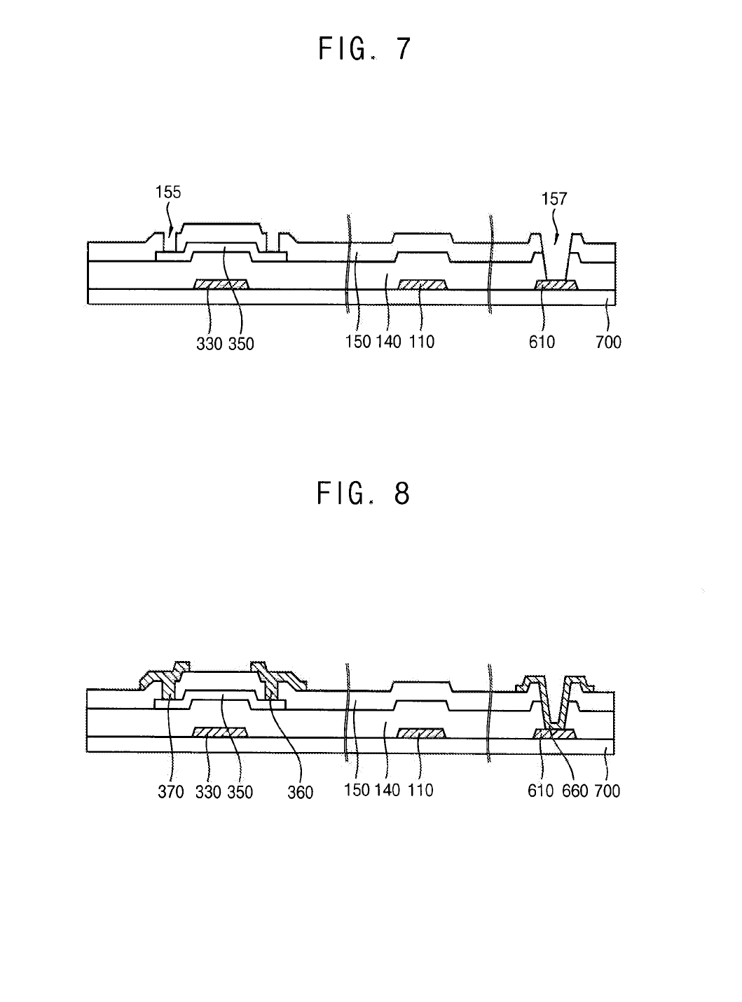

Referring to FIG. 7, the etch stop layer 150 partially covering the active layer 350 can be formed on the gate insulation layer 140.

According to example embodiments, an insulation layer at least partially covering the active layer 350 can be formed at least partially of an insulation material, e.g., silicon oxide or silicon nitride on the gate insulation layer 140. After a formation of the insulation layer, a first opening 155 at least partially exposing an upper surface of the active layer 350 can be formed by etching the insulation layer. In some embodiments, the first opening 155 does not overlap the active layer 350. In some embodiments, the width of the first opening can be substantially uniform. In some embodiments, there can be a plurality of the first openings 155 partially exposing different portions of the active layer 350. The first openings 155 can have substantially the same width.

In example embodiments, the insulation layer or the etch stop layer 150 can be formed to substantially cover the first signal line 110 and the pad 610. The insulation layer can be formed by CVD, spin coating, vapor deposition, etc.

In example embodiments, a second opening 157 can be formed at substantially the same time as the first opening 155. The second opening 157 can be formed to at least partially expose a portion of the pad 610 by etching the etch stop layer 150 and the gate insulation layer 140. The second opening 157 and the first opening 155 can have different widths. In some embodiments, the width of the second opening 157 can be larger at its top portion than at the bottom portion. The first opening 155 and the second opening 157 can be formed at substantially the same time by the same etching process using one mask, or the first opening 155 and the second opening 157 can be formed individually by different etching processes by using different masks.

Referring to FIG. 8, the source electrode 360 and the drain electrode 370 can be formed on the etch stop layer 150.

According to example embodiments, a second conductive layer filling the first opening 155 can be formed on the etch stop layer 150. The second conductive layer can also be formed on the side walls and the bottom portion of the second opening 157. The second conductive layer can contact the active layer 350 and the pad 610. After a formation of the second conductive layer, the source electrode 360 and the drain electrode 370 can be formed by patterning the second conductive layer by a patterning process, e.g., photolithography.

In example embodiments, the barrier conductive layer 660 can contact the pad 610 via the second opening 157. The barrier layer 660, the source electrode 360, and drain electrode 370 can be formed at substantially the same time. In some embodiments, the source electrode 360, the drain electrode 370 and the barrier conductive layer 660 can be formed by the deposition and etching of the second conductive layer. In some embodiments, portions of the barrier conductive layer 660 do not overlap the pad 610.

The second conductive layer can be formed by sputtering, ALD or PLD at least partially of a metal (e.g., titanium or molybdenum), a nitride of the metal (e.g., titanium nitride or molybdenum nitride) and/or a conductive metal oxide. The conductive metal oxide can include ITO, IZO, AZO, tin oxide, indium oxide, gallium oxide or a combination thereof. When formed at least partially of the above-mentioned materials, the barrier conductive layer 660 can have a high resistance to corrosion and oxidation.

On the other hand, the portion of the active layer 350 that crosses the first gate electrode 330 can serve as a channel in which electrical charges move. The channel can be substantially protected by the etch stop layer 150 during the etching process to form the source electrode 360 and the drain electrode 370.

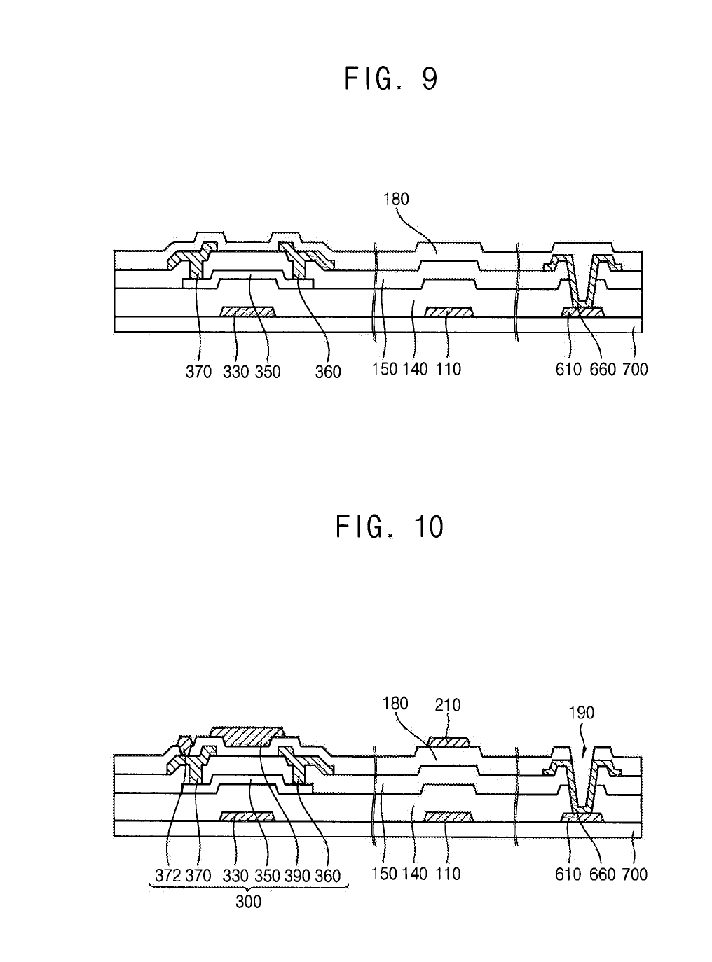

Referring to FIG. 9, the passivation layer 180 can be formed on the etch stop layer 150. According to example embodiments, the passivation layer 180 can be formed to substantially cover the first signal line 110. In some embodiments, at least part of the passivation layer 180 can have substantially the same thickness as the etch stop layer 150.

The passivation layer 180 can be formed by CVD, spin coating, printing, vapor deposition, etc.

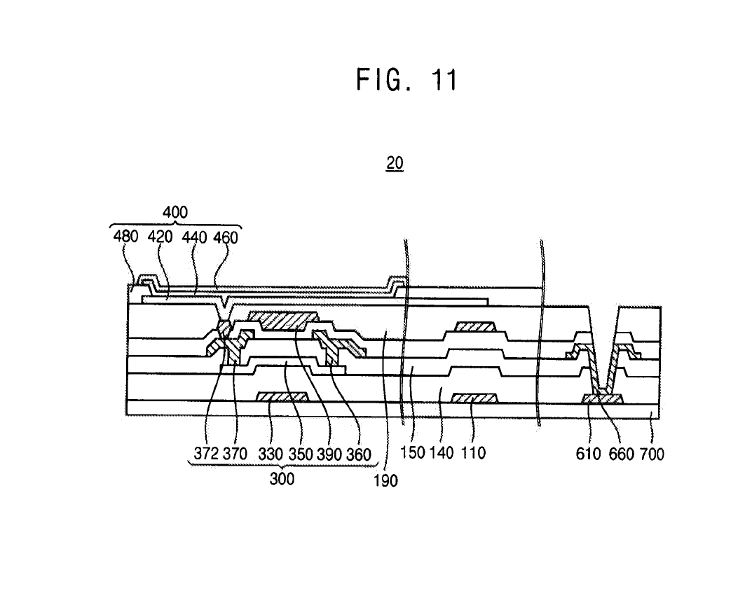

Referring to FIG. 10, the second gate electrode 390 and the second signal line 210 can be formed on the passivation layer 180. In example embodiments, the pixel contact 372 can be formed at substantially the same time as the second gate electrode 390 and the second signal line 210.

According to example embodiments, a contact hole exposing a portion of the drain electrode 370 can be formed by etching the passivation layer 180. The pixel contact 372, the second gate electrode 390 and the second signal line 210 can be formed by a step of forming a third conductive layer filling the contact hole on the passivation layer 180, and a step of patterning the third conductive layer by a patterning process, e.g., photolithography. The pixel contact 372, the second gate electrode 390 and the second signal line 210 can be formed by the deposition and etching of the same conductive layer.

The third conductive layer can be formed at least partially of a metal that has a low resistance (e.g., copper, aluminum, gold, silver, tungsten, etc.) by sputtering, ALD, PLD or CVD. The second signal line 210, the second gate electrode 390 and the pixel contact 372 can be formed to have a relatively large thickness in order to maintain a sufficiently low resistance. For example, the second signal line 210, the second gate electrode 390 and the pixel contact 372 can have a thickness of about 2000 Å, but is not limited thereto. The width of the second gate electrode 390 can be greater than that of the first gate electrode 330. The width of the second signal line 210 can be less than that of the first signal line 110.

In example embodiments, a third opening 190 at least partially exposing an upper surface of the barrier conductive layer 660 can be formed by etching the passivation layer 180. An additional line structure of the display device or a contact structure connected to the pixel can be electrically connected to the pad 610 via the third opening 190.

Because the second gate electrode 390 and the first gate electrode 330 can form the double channels in the active layer 350, a sufficient current can be generated by low current or low voltage.

FIG. 11 is a cross-sectional view illustrating the display device 20 according to example embodiments.

Referring to FIG. 11, the display device 20 can include the first signal line 110, the second signal line 210, the TFT 300, and the pixel element 400.

The display device 20 can be an OLED display, an LCD, PDP display, etc. The FIG. 11 illustrates the OLED display including an OLED as an example of the display device 20.

The pixel element 400 can be electrically connected to the TFT 300 and emit a light having a specific wavelength based on the electrical signal provided from the TFT 300. In example embodiments, the pixel element 400 can be an OLED. For example, the pixel element 400 can include a pixel electrode 420, an opposite electrode 460, and a light-emitting layer 440 interposed between the pixel electrode 420 and the opposite electrode 460. The OLED can emit the light when a predetermined voltage is applied between the pixel electrode 420 and the opposite electrode 460.

The pixel electrode 420 can be electrically connected to the TFT 300 and serve as a reflective electrode or a transmissive electrode according to emission types of the display device 20. For example, when the display device 20 is a top emission type, the pixel electrode 420 can be the reflective electrode formed at least partially of a metal or an alloy of the metal that have relatively high reflectivity. On the other hand, when the display device 20 is a bottom emission type, the pixel electrode 420 can be the transmissive electrode formed at least partially of a transparent material.

The light-emitting layer 440 can emit the light by receiving electrons and holes from the pixel electrode 420 and the opposite electrode 460. The light-emitting layer 440 can be formed at least partially of an organic material and a light-emitting host (e.g., tris(8-hydroxyquinolinato)aluminum (Alq3), 9,10-di(naphty-2-yl)anthracene (AND), 1,3-bis(carbazol-9-yl)benzene (mCP), 1,3,5-tris(carbazol-9-yl)benzene (tCP), etc.), a light-emitting dopant (e.g., tris[1-phenylisoquinoline-C2, N]iridium(3) (Ir(piq)3), tris[2-phenylpyridinato-C2,N]iridium(3) (Ir(ppy)3), iridium(3) bis[4,6-difluorophenyl-pyridinato-N,C2] (F2Irpic), etc.), or a combination thereof.

In example embodiments, the pixel element 400 can further include a hole injection layer, a hole transport layer, an electron transport layer, and an electron injection layer that are interposed between the pixel electrode 420 and the opposite electrode 460.

When the display device 20 is the top emission type, the opposite electrode 460 can be a transmissive electrode. When the display device 20 is the bottom emission type, the opposite electrode 460 can be a reflective electrode.

Although a few example embodiments (e.g., a display substrate, a method of manufacturing a display substrate and a display device) have been described, those skilled in the art will readily appreciate that many modifications are possible in the example embodiments without materially departing from the novel teachings and advantages of the described technology.

The described technology can be applied to any suitable display device. For example, the described technology can be applied to an OLED display, a LCD, a PDP display, etc. Furthermore, the technology can be applied as a display for various types of electronic products such as a television (TV), a desktop computer, a tablet computer, a laptop computer, a mobile phone, a GPS receiver, a MP3 player, a smart pad, a personal digital assistant (PDA), etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A display substrate, comprising:
a base substrate;
a first gate electrode formed on the base substrate;
a scan line electrically connected to the first gate electrode;
a gate insulation layer, an etch stop layer and a passivation layer formed on the base substrate to at least partially overlap the first gate electrode and the scan line; and
a data line formed on the passivation layer to at least partially overlap the scan line.

2. The display substrate of claim 1, wherein the scan line is formed on the same level as that of the first gate electrode, and wherein the scan line is formed of the same material as that of the first gate electrode.

3. The display substrate of claim 2, wherein the data line crosses the scan line, and wherein the gate insulation layer, the etch stop layer and the passivation layer are stacked between the scan line and the data line and formed in an intersection region of the data line and the scan line.

4. The display substrate of claim 1, further comprising:
an active layer at least partially covered by the etch stop layer; and
a source electrode and a drain electrode formed on the etch stop layer and electrically connected to the active layer.

5. The display substrate of claim 4, further comprising a pad electrically connected to the scan line, wherein the pad is formed on the same level as that of the scan line, and wherein the pad is formed of the same material as that of the scan line.

6. The display substrate of claim 5, wherein the pad is formed using at least one of copper (Cu), aluminum (Al), gold (Au), silver (Ag), tungsten (W) or a combination thereof.

7. The display substrate of claim 5, further comprising a barrier conductive layer formed on the pad, wherein the barrier conductive layer is formed of the same material as that of the source electrode and the drain electrode.

8. The display substrate of claim 7, wherein the source electrode, the drain electrode and the barrier conductive layer are formed using at least one of titanium (Ti), molybdenum (Mo), titanium nitride, molybdenum nitride, a conductive metal oxide or a combination thereof.

9. The display substrate of claim 4, further comprising a second gate electrode formed on the passivation layer, wherein each of the first and second gate electrodes substantially overlaps the active layer.

10. The display substrate of claim 9, wherein the second gate electrode is formed on the same level as that of the data line, and wherein the second gate electrode is formed of the same material as that of the data line.

11. The display substrate of claim 4, further comprising a pixel contact electrically connected to the drain electrode, wherein the pixel contact is formed of the same material as that of the data line.

12. A method of manufacturing a display substrate, the method comprising:
forming a first gate electrode and a scan line to be electrically connected to the first gate electrode on a base substrate;
forming a gate insulation layer on the base substrate to substantially cover the first gate electrode and the scan line;
forming an active layer on the gate insulation layer to substantially overlap the first gate electrode;
forming an etch stop layer on the gate insulation layer to at least partially cover the active layer;
forming a source electrode and a drain electrode on the etch stop layer to be electrically connected to the active layer;
forming a passivation layer on the etch stop layer to substantially cover the source electrode and the drain electrode; and
forming a data line on the passivation layer to at least partially overlap the scan line.

13. The method of claim 12, wherein the etch stop layer and the passivation layer substantially cover the scan line.

14. The method of claim 13, further comprising forming a pad on the base substrate to be electrically connected to the scan line, wherein the pad, the first gate electrode and the scan line are formed substantially simultaneously by a patterning process using a first conductive layer.

15. The method of claim 14, further comprising:
partially etching the etch stop layer and the gate insulation layer to form an opening through which the pad is exposed; and
forming a barrier conductive layer to be electrically connected to the pad via the opening.

16. The method of claim 15, wherein the barrier conductive layer, the source electrode and the drain electrode are formed substantially simultaneously by a patterning process using a second conductive layer, and wherein the second conductive layer is formed using at least one of titanium, molybdenum, titanium nitride, molybdenum nitride, a conductive metal oxide or a combination thereof.

17. The method of claim 12, further comprising forming a second gate electrode to at least partially overlap the active layer.

18. The method of claim 17, further comprising forming a pixel contact electrically connected to the drain electrode, wherein the pixel, the second gate electrode and the data line are formed substantially simultaneously by a patterning process using a third conductive layer.

19. A display device, comprising:
a first gate electrode formed on a base substrate;
a scan line electrically connected to the first gate electrode;
a gate insulation layer, an etch stop layer and a passivation layer formed on the base substrate to at least partially cover the first gate electrode and the scan line;
an active layer at least partially covered by the etch stop layer,
a source electrode and a drain electrode formed on the etch stop layer to be electrically connected to the active layer;
a data line formed on the passivation layer to at least partially overlap the scan line;
a pixel electrode electrically connected to the drain electrode;
a light-emitting layer formed on the pixel electrode; and
an opposite electrode formed on the light-emitting layer.

20. The display device of claim 19, further comprising a second gate electrode formed on the passivation layer to at least partially overlap the active layer, wherein the second gate electrode is formed on the same level as that of the data line, and wherein the second gate electrode is formed of the same material as that of the data line.
